(19) United States
(12) Patent Application Publication
(10) Pub. No.: US 2026/0231492 A1
(43) Pub. Date: Aug. 6, 2026

(54) METHOD OF MANUFACTURING SEMICONDUCTOR DEVICE AND SEMICONDUCTOR DEVICE

(71) Applicant: RENESAS ELECTRONICS CORPORATION, Tokyo (JP)

(72) Inventor: Yudai HIGA, Tokyo (JP)

(21) Appl. No.: 19/424,883

(22) Filed: Dec. 18, 2025

(30) Foreign Application Priority Data
Jan. 31, 2025 (JP) 2025-014852

(51) Int. Cl. H10D 62/60; H10D 30/01; H10D 30/65; H10D 62/834

(52) U.S. Cl. CPC H10D 62/60; H10D 30/0281; H10D 30/655; H10D 62/834

(57) ABSTRACT

A method of manufacturing a semiconductor device includes forming a trench at an upper surface of a first semiconductor layer, introducing a first impurity of a first conductivity type into the first semiconductor layer in an element formation region, forming a first impurity region by diffusing the first impurity by heat treatment, forming a second semiconductor layer on the first semiconductor layer by epitaxial growth, introducing a second impurity of the first conductivity type into the second semiconductor layer, forming a second impurity region so as to be connected to the first impurity region by diffusing the second impurity by heat treatment, and forming a semiconductor element on the second semiconductor layer.

### CROSS‑REFERENCE TO RELATED APPLICATIONS

The disclosure of Japanese Patent Application No. 2025‑014852 filed on January 31, 2025 including the specification, drawings and abstract is incorporated herein by reference in its entirety.

### BACKGROUND

The present disclosure relates to a method of manufacturing a semiconductor device and to a semiconductor device.

A semiconductor device capable of carrying a large current has been developed.

There are disclosed techniques listed below.

[Patent Document 1] Japanese Unexamined Patent Application Publication No. 2015‑216218

[Patent Document 2] Japanese Unexamined Patent Application Publication No. 2017‑152559

[Patent Document 3] Japanese Unexamined Patent Application Publication No. 2019‑192741

[Patent Document 4] Japanese Unexamined Patent Application Publication No. 2023‑173190

[Patent Document 5] Japanese Unexamined Patent Application Publication No. 2024‑76158

### SUMMARY

The method of manufacturing the semiconductor device described above includes a heat treatment step of activating a buried impurity region and a heat treatment step of forming a sinker connected to the buried impurity region. During the heat treatment, impurities in the buried impurity region may laterally diffuse, and a depletion layer extending from the buried impurity region may expand. To prevent the depletion layer extending from the buried impurity region from connecting to a depletion layer extending from another buried impurity region, it is necessary to increase the interval between adjacent buried impurity regions. In other words, it is necessary to increase the distance between adjacent semiconductor elements. As a result, the size of the semiconductor device increases.

An object of the present disclosure is to suppress diffusion of impurities in a buried impurity region and to suppress extension of a depletion layer.

Other objects and novel features will become apparent from the description of the present specification and the accompanying drawings.

According to one embodiment, a method of manufacturing a semiconductor device includes a step of forming a trench at an upper surface of a semiconductor layer, a step of introducing an impurity into the semiconductor layer so as to be spaced apart from the trench, and a step of forming an impurity region by diffusing the impurity by heat treatment.

According to one embodiment, diffusion of impurities in a buried impurity region can be suppressed, and extension of a depletion layer can be suppressed.

### BRIEF DESCRIPTION OF THE DRAWINGS

FIG. 1 is a plan view illustrating a semiconductor device of related art.

FIG. 2 is a cross‑sectional view of the semiconductor device illustrated along line A‑A of FIG. 1.

FIG. 3 is a flow diagram illustrating a method of manufacturing the semiconductor device of related art.

FIG. 4 is a flow diagram illustrating the method of manufacturing the semiconductor device of related art.

FIG. 5 is a flow diagram illustrating the method of manufacturing the semiconductor device of related art.

FIG. 6 is a flow diagram illustrating the method of manufacturing the semiconductor device of related art.

FIG. 7 is a flow diagram illustrating the method of manufacturing the semiconductor device of related art.

FIG. 8 is a flow diagram illustrating the method of manufacturing the semiconductor device of related art.

FIG. 9 is a flow diagram illustrating the method of manufacturing the semiconductor device of related art.

FIG. 10 is a diagram illustrating a problem in the method of manufacturing the semiconductor device of related art.

FIG. 11 is a diagram illustrating the problem in the method of manufacturing the semiconductor device of related art.

FIG. 12 is a flow diagram illustrating a first method of manufacturing a semiconductor device of the present disclosure.

FIG. 13 is a flow diagram illustrating the first method of manufacturing the semiconductor device of the present disclosure.

FIG. 14 is a flow diagram illustrating the first method of manufacturing the semiconductor device of the present disclosure.

FIG. 15 is a flow diagram illustrating the first method of manufacturing the semiconductor device of the present disclosure.

FIG. 16 is a flow diagram illustrating the first method of manufacturing the semiconductor device of the present disclosure.

FIG. 17 is a flow diagram illustrating the first method of manufacturing the semiconductor device of the present disclosure.

FIG. 18 is a flow diagram illustrating the first method of manufacturing the semiconductor device of the present disclosure.

FIG. 19 is a flow diagram illustrating the first method of manufacturing the semiconductor device of the present disclosure.

FIG. 20 is a flow diagram illustrating the first method of manufacturing the semiconductor device of the present disclosure.

FIG. 21 is a flow diagram illustrating the first method of manufacturing the semiconductor device of the present disclosure.

FIG. 22 is a diagram illustrating extension of a depletion layer in the semiconductor device of the present disclosure.

FIG. 23 is a diagram illustrating the extension of the depletion layer in the semiconductor device of the present disclosure.

FIG. 24 is a flow diagram illustrating a second method of manufacturing the semiconductor device of the present disclosure.

FIG. 25 is a flow diagram illustrating the second method of manufacturing the semiconductor device of the present disclosure.

FIG. 26 is a flow diagram illustrating the second method of manufacturing the semiconductor device of the present disclosure.

FIG. 27 is a flow diagram illustrating the second method of manufacturing the semiconductor device of the present disclosure.

FIG. 28 is a flow diagram illustrating the second method of manufacturing the semiconductor device of the present disclosure.

FIG. 29 is a flow diagram illustrating the second method of manufacturing the semiconductor device of the present disclosure.

FIG. 30 is a diagram illustrating an effect of the second method of manufacturing the semiconductor device of the present disclosure.

FIG. 31 is a flow diagram illustrating a third method of manufacturing the semiconductor device of the present disclosure.

FIG. 32 is a flow diagram illustrating the third method of manufacturing the semiconductor device of the present disclosure.

FIG. 33 is a flow diagram illustrating the third method of manufacturing the semiconductor device of the present disclosure.

FIG. 34 is a flow diagram illustrating the third method of manufacturing the semiconductor device of the present disclosure.

FIG. 35 is a flow diagram illustrating the third method of manufacturing the semiconductor device of the present disclosure.

FIG. 36 is a flow diagram illustrating the third method of manufacturing the semiconductor device of the present disclosure.

FIG. 37 is a diagram illustrating a resistance obtained by the third method of manufacturing the semiconductor device of the present disclosure.

FIG. 38 is a flow diagram illustrating a fourth method of manufacturing the semiconductor device of the present disclosure.

FIG. 39 is a flow diagram illustrating the fourth method of manufacturing the semiconductor device of the present disclosure.

FIG. 40 is a flow diagram illustrating the fourth method of manufacturing the semiconductor device of the present disclosure.

FIG. 41 is a flow diagram illustrating the fourth method of manufacturing the semiconductor device of the present disclosure.

FIG. 42 is a flow diagram illustrating the fourth method of manufacturing the semiconductor device of the present disclosure.

FIG. 43 is a flow diagram illustrating the fourth method of manufacturing the semiconductor device of the present disclosure.

FIG. 44 is a flow diagram illustrating a fifth method of manufacturing the semiconductor device of the present disclosure.

FIG. 45 is a flow diagram illustrating the fifth method of manufacturing the semiconductor device of the present disclosure.

FIG. 46 is a flow diagram illustrating the fifth method of manufacturing the semiconductor device of the present disclosure.

FIG. 47 is a flow diagram illustrating the fifth method of manufacturing the semiconductor device of the present disclosure.

FIG. 48 is a flow diagram illustrating the fifth method of manufacturing the semiconductor device of the present disclosure.

FIG. 49 is a flow diagram illustrating the fifth method of manufacturing the semiconductor device of the present disclosure.

### DETAILED DESCRIPTION

Embodiments of the present invention will be described with reference to the drawings. However, the invention according to the claims is not limited to the embodiments described below. In addition, not all of the configurations described in the embodiments are necessarily essential as means for solving the problem. For clarity of explanation, the following description and the drawings are appropriately omitted or simplified. In the drawings, the same reference numerals denote the same elements, and redundant description is omitted as appropriate.

### SEMICONDUCTOR DEVICE OF RELATED ART

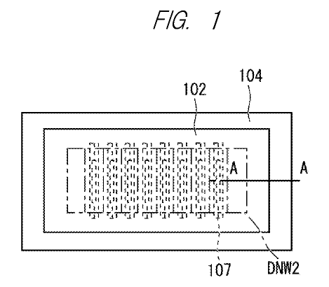

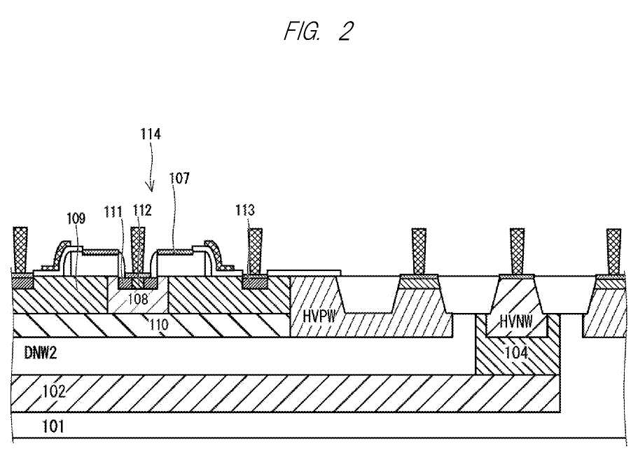

FIG. 1 is a plan view illustrating a semiconductor device of related art. FIG. 2 is a cross‑sectional view of the semiconductor device illustrated along line A‑A of FIG. 1. FIGS. 3 to 9 are flow diagrams illustrating a method of manufacturing the semiconductor device of related art. The semiconductor device of related art will be described below with reference to FIGS. 1 to 9. The semiconductor device of related art is a so‑called Laterally Diffused Metal Oxide Semiconductor Field Effect Transistor (LDMOSFET), which is a type of power device.

A first semiconductor layer 101 is a semiconductor substrate made of single‑crystal silicon or the like. Although, it is preferable to use a p‑type semiconductor substrate as the semiconductor substrate, an n‑type semiconductor substrate may also be used. In addition, an epitaxial wafer in which an epitaxial semiconductor layer is formed on a semiconductor substrate may also be used as the semiconductor substrate.

The semiconductor substrate has an upper surface and a back surface located opposite to the upper surface. On the upper surface of the semiconductor substrate, a Shallow Trench Isolation (STI) region (element isolation region) is formed by an STI method. The STI region is made of an insulator (insulating film) buried in a trench formed in the semiconductor substrate.

In another embodiment, a LOCal Oxidation of Silicon (LOCOS) region may be formed by using a LOCOS method instead of the STI region. It is also possible that neither an STI region nor a LOCOS region is formed.

The semiconductor substrate has a p‑type substrate region 110. The p‑type substrate region 110 is a p‑type semiconductor region. The p‑type substrate region 110 may be a p‑type semiconductor region formed in a p‑type semiconductor substrate, a p‑type semiconductor region formed in an n‑type semiconductor substrate, or a region that remains p‑type in a p‑type semiconductor substrate. The p‑type substrate region may also be a p‑type epitaxial semiconductor layer formed on a p‑type or n‑type semiconductor substrate. In the semiconductor substrate, an n‑type buried layer serving as a first impurity region 102 may be formed under the p‑type substrate region 110.

An element formation region is included in the p‑type substrate region 110 in plan view. The term “in plan view” refers to a view taken along a plane substantially parallel to the upper surface of the semiconductor substrate. Accordingly, an n‑type source region 111, an n‑type drain region 113, and a channel formation region of the LDMOSFET formed in the element formation region are formed in the p‑type substrate region 110 in plan view.

In the semiconductor substrate, an n‑type drift region 109 and a p‑type body region 108 are formed in an upper portion of the p‑type substrate region 110. The n‑type drift region 109 and the p‑type body region 108 are adjacent to or spaced apart from each other in the gate length direction of the LDMOSFET. The gate length direction of the LDMOSFET coincides with the channel length direction of the LDMOSFET, and the gate width direction of the LDMOSFET coincides with the channel width direction of the LDMOSFET.

The n‑type drift region 109 includes the n‑type drain region 113, and the p‑type body region 108 includes the n‑type source region. The n‑type drift region 109 and the p‑type body region 108 each reach the upper surface of the semiconductor substrate. Each of a bottom surface of the n‑type drift region 109 and a bottom surface of the p‑type body region 108 is in contact with the p‑type substrate region 110. In other words, the bottom surfaces of the n‑type drift region 109 and the p‑type body region 108 each are covered with the p‑type substrate region 110. A PN junction is formed at a boundary between the n‑type drift region 109 and the p‑type substrate region 110. The impurity concentration (p‑type impurity concentration) of the p‑type body region 108 is higher than the impurity concentration (p‑type impurity concentration) of the p‑type substrate region 110.

The p‑type body region 108 is formed so as to surround the n‑type source region 111 and a p‑type body contact region 112, which will be described later. The p‑type body region 108 can function as a back gate. The p‑type body region 108 can also function as a punch‑through stopper that suppresses extension of a depletion layer from the drain to the source of the LDMOSFET.

In the semiconductor substrate, the n‑type source region 111 and the p‑type body contact region 112 (p‑type semiconductor region) are formed in the p‑type body region 108. The n‑type source region 111 is an n‑type semiconductor region that functions as a source region of the LDMOSFET. A portion of the p‑type body region 108 is located under a gate electrode 107 between the n‑type source region 111 and the n‑type drain region 113. An upper portion (upper layer portion) of the p‑type body region 108 located under the gate electrode 107 between the n‑type source region 111 and the n‑type drain region 113 is a channel formation region of the LDMOSFET.

The n‑type source region 111 and the p‑type body contact region 112 each extend in the gate width direction of the LDMOSFET, and in the gate length direction of the LDMOSFET, the n‑type source region 111 and the p‑type body contact region 112 are adjacent to each other. The n‑type source region 111 is located between the channel formation region and the p‑type body contact region 112. Each of a bottom surface of the n‑type source region 111 and a bottom surface of the p‑type body contact region 112 is in contact with the p‑type body region 108. In other words, the bottom surface of the n‑type source region 111 and the bottom surface of the p‑type body contact region 112 are covered with the p‑type body region 108. An upper surface of the n‑type source region 111 and an upper surface of the p‑type body contact region 112 reach the upper surface of the semiconductor substrate. In addition, a Lightly Doped Drain (LDD) structure may be applied to the n‑type source region 111.

The impurity concentration of the p‑type body contact region 112 is higher than that of the p‑type body region 108. The p‑type body contact region 112 can function as a contact portion of the p‑type body region 108.

In the n‑type drift region 109, the n‑type drain region 113 (n‑type semiconductor region) is formed. The n‑type drain region 113 is an n‑type semiconductor region that functions as a drain region of the LDMOSFET. The n‑type drain region 113 extends in the channel width direction, and an upper surface of the n‑type drain region 113 reaches the upper surface of the semiconductor substrate. The impurity concentration of the n‑type drain region 113 is higher than that of the n‑type drift region 109. The n‑type drain region 113 and the n‑type source region 111 are spaced apart from each other in the channel length direction.

The gate electrode 107 of the LDMOSFET is formed on the upper surface of the semiconductor substrate via a gate insulating film. Specifically, the gate electrode 107 is formed on the upper surface of the semiconductor substrate between the n‑type source region 111 and the n‑type drain region 113 via the gate insulating film. The gate insulating film is made of, for example, a silicon oxide film. The gate electrode 107 is made of, for example, a single layer film of polycrystalline silicon (doped polysilicon) or a laminated film of a polycrystalline silicon film and a metal silicide layer.

A bottom surface of the n‑type drain region 113 is in contact with the n‑type drift region 109, and a side surface of the n‑type drain region 113 is in contact with the n‑type drift region 109. In other words, the bottom surface of the n‑type drain region 113 is covered with the n‑type drift region 109, and the side surface of the n‑type drain region 113 is covered with the n‑type drift region 109. Therefore, the n‑type drift region 109 can also function as a conduction path between a channel of the LDMOSFET and the n‑type drain region 113.

Sidewall spacers made of an insulating film (for example, a silicon oxide film) are formed on both side surfaces of the gate electrode 107.

The p‑type body region 108 and the n‑type drift region 109 each extend in the channel width direction. A portion of the p‑type body region 108 is located under the gate electrode 107, and a portion of the n‑type drift region 109 is also located under the gate electrode 107. In other words, a portion of the gate electrode 107 overlaps the p‑type body region 108 in plan view, and another portion of the gate electrode 107 overlaps the n‑type drift region 109 in plan view.

In the channel length direction, the p‑type body region 108 and the n‑type drift region 109 are in contact with each other. A PN junction is formed at a boundary between the p‑type body region 108 and the n‑type drift region 109.

A side surface of the n‑type drift region 109 is located under the gate electrode 107 in the channel length direction and extends in the channel width direction.

In plan view, the gate electrode 107 is disposed between the n‑type source region 111 and the n‑type drain region 113. When a voltage equal to or higher than a threshold voltage is applied to the gate electrode 107, an n‑type inversion layer is formed in an upper portion (upper layer portion) of the p‑type body region 108 located under the gate electrode 107. The n‑type inversion layer functions as a channel (channel region). The n‑type source region 111 and the n‑type drain region 113 become conductive through the channel and the n‑type drift region 109.

In the channel length direction, the n‑type drift region 109 having an impurity concentration (n‑type impurity concentration) lower than that of the n‑type drain region 113 is interposed between the p‑type body region 108 and the n‑type drain region 113. Accordingly, the n‑type drift region 109 having the impurity concentration lower than that of the n‑type drain region 113 is formed between the channel formation region of the LDMOSFET and the n‑type drain region 113. Therefore, in the channel length direction, the channel formation region and the n‑type drift region 109 are located between the n‑type source region 111 and the n‑type drain region 113. In addition, the p‑type substrate region 110 located under the n‑type drift region 109 and the p‑type body region 108 can function as a RESURF layer (RESURF region).

Metal silicide layers may be formed on each of the n‑type drain region 113, the n‑type source region 111, and the p‑type body contact region 112. The metal silicide layers can be formed by using a Salicide (Self Aligned Silicide) technique.

In addition, the n‑type drain region 113 is in contact with the n‑type drift region 109. Accordingly, the n‑type drain region 113 and the n‑type drift region 109 are electrically connected to each other. In another embodiment, the n‑type drain region 113 may not be in contact with the n‑type drift region 109, and an n‑type semiconductor region having an impurity concentration higher than that of the n‑type drift region 109 and lower than that of the n‑type drain region 113 may be interposed between the n‑type drain region 113 and the n‑type drift region 109. In this case, the n‑type drain region 113 and the n‑type drift region 109 are electrically connected to each other via the n‑type semiconductor region interposed therebetween.

The semiconductor device of related art includes a semiconductor substrate, a semiconductor element 114, a first impurity region 102, a second impurity region 104, and an electrode HVNW. The semiconductor substrate includes a first semiconductor layer 101 and a second semiconductor layer 103 formed on the first semiconductor layer 101. A first‑conductivity‑type buried first impurity region 102 is formed in the first semiconductor layer 101 and is located under the semiconductor element 114. The semiconductor element 114 is formed in an element formation region. A first conductivity type is n‑type, and a second conductivity type is p‑type.

As illustrated in FIG. 2, the first impurity region 102 is located under the entire semiconductor element 114. A sinker serving as the second impurity region 104 is formed so as to surround the element formation region and is connected to the first impurity region 102. The second impurity region 104 exhibits the first conductivity type. The first impurity region 102 is electrically connected to the electrode HVNW formed on the upper surface of the semiconductor substrate via the second impurity region 104.

Hereinafter, a method of manufacturing the semiconductor device of related art will be described with reference to FIGS. 3 to 9. As illustrated in FIG. 3, first, a first semiconductor layer 101 is prepared. The first semiconductor layer 101 may be formed on a support substrate by an epitaxial growth method after preparing the support substrate. The first semiconductor layer 101 has a first conductivity type. Next, as illustrated in FIG. 4, a first impurity region 102 is formed in the first semiconductor layer 101 by introducing a first impurity into the first semiconductor layer 101. The first impurity is, for example, antimony. Next, the first impurity region 102 is activated by performing a heat treatment on the first semiconductor layer 101.

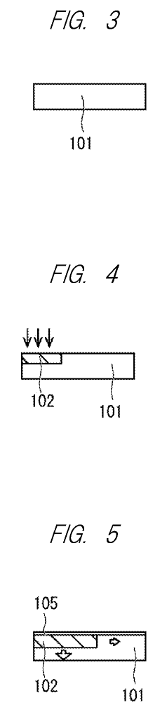

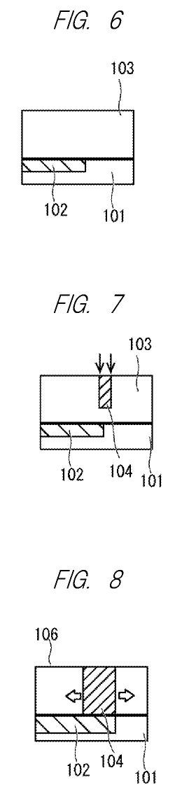

As illustrated in FIG. 5, the first impurity diffuses by the heat treatment, and the first impurity region 102 expands. At this point, an oxide film 105 is formed on the upper surface of the first semiconductor layer 101 by the heat treatment. Before forming a second semiconductor layer 103, the oxide film 105 is removed. Next, as illustrated in FIG. 6, the second semiconductor layer 103 is formed on the first semiconductor layer 101 by an epitaxial growth method. The thickness of the second semiconductor layer 103 is, for example, 4 μm or more and 6 μm or less. Next, as illustrated in FIG. 7, a second impurity region 104 is formed in the second semiconductor layer 103 by introducing a second impurity of the first conductivity type into the second semiconductor layer 103. The second impurity is, for example, phosphorus (P).

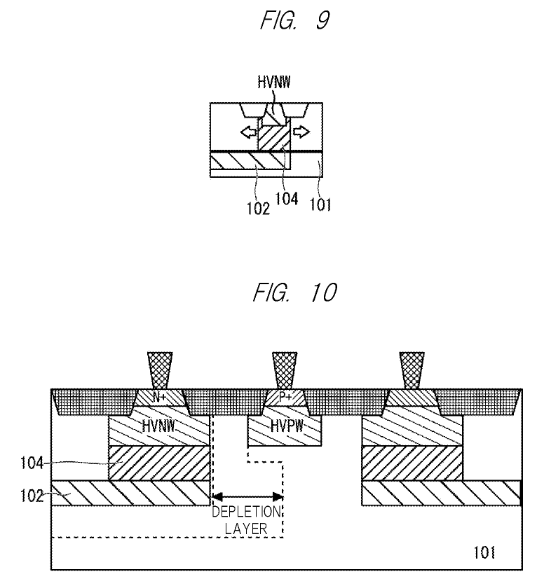

Next, as illustrated in FIG. 8, the second impurity diffuses by performing the heat treatment on the second semiconductor layer 103, and the second impurity region 104 expands. As a result, the second impurity region 104 is connected to the first impurity region 102. The second impurity region 104 functions as a sinker. At this point, an oxide film 106 is formed on an upper surface of the second semiconductor layer 103. Subsequently, a semiconductor element 114 is formed in the element formation region. In addition, as illustrated in FIG. 9, an electrode HVNW is formed in the second impurity region 104.

### PROBLEM IN METHOD OF MANUFACTURING SEMICONDUCTOR DEVICE OF RELATED ART

FIGS. 10 and 11 are diagrams illustrating a problem in the method of manufacturing the semiconductor device of related art. The problem in the method of manufacturing the semiconductor device of related art will be described with reference to FIGS. 10 and 11.

As illustrated in FIG. 10, in the semiconductor device of related art, a depletion layer spread from the first impurity region 102 and the second impurity region 104 due to diffusion of the first impurity and the second impurity caused by the heat treatment. As illustrated in FIG. 11, when the depletion layer reaches another adjacent impurity region, the first impurity region 102 and the second impurity region 104 become conductive with the other adjacent impurity region due to punch‑through. In order to prevent the first impurity region 102 and the second impurity region 104 from becoming conductive with the other adjacent impurity region due to punch‑through, the distance between the first impurity region 102 and the other impurity region must be increased. However, increasing this distance results in an increase in the size of the semiconductor device.

### FIRST METHOD OF MANUFACTURING SEMICONDUCTOR DEVICE OF PRESENT DISCLOSURE

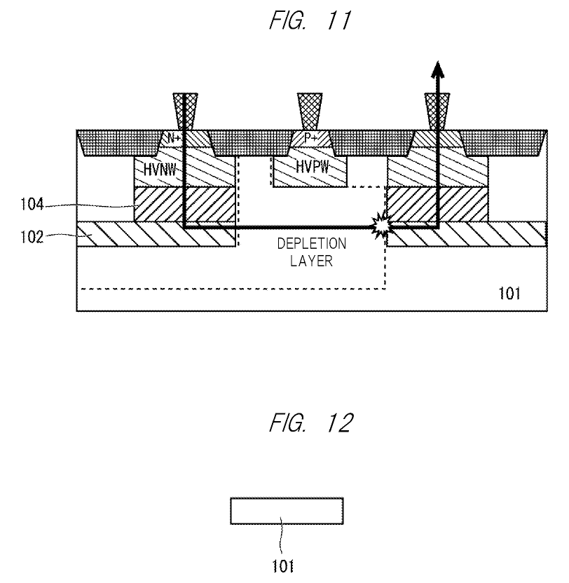

FIGS. 12 to 21 illustrate a flow of a first method of manufacturing the semiconductor device of the present disclosure. Referring to FIGS. 12 to 21, the first method of manufacturing the semiconductor device of the present disclosure will be described below.

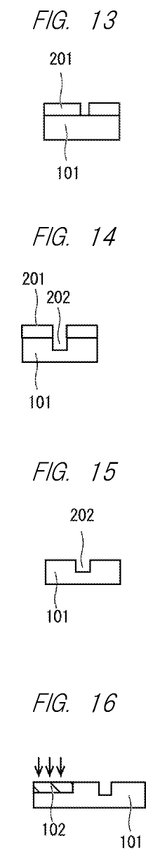

As illustrated in FIG. 12, first, a first semiconductor layer 101 is prepared. The first semiconductor layer 101 may be formed on a support substrate by an epitaxial growth method after preparing the support substrate. Next, an alignment mark is formed on an upper surface of the first semiconductor layer 101. The alignment mark is used for aligning a photolithography position with respect to the first semiconductor layer 101. In the same step as the alignment mark, a trench 202 is formed at the upper surface of the first semiconductor layer 101. The trench 202 may be formed in a step different from that of the alignment mark; however, by forming the trench 202 in the same step as the alignment mark, the manufacturing cost can be reduced. The trench 202 is formed so as to surround an element formation region. For example, as illustrated in FIG. 13, a resist film 201 is formed on the first semiconductor layer 101 by a photolithography technique. Next, as illustrated in FIG. 14, the first semiconductor layer 101 is etched by using the resist film as a mask. Thereafter, as illustrated in FIG. 15, the alignment mark and the trench 202 are formed at the upper surface of the first semiconductor layer 101 by removing the resist film. The trench 202 is also referred to as a first trench. And the alignment mark is also referred to as a second trench. Next, as illustrated in FIG. 16, a first impurity of a first conductivity type is implanted into the first semiconductor layer 101 so as to be spaced apart from the trench 202, thereby forming a first impurity region 102 in the first semiconductor layer 101.

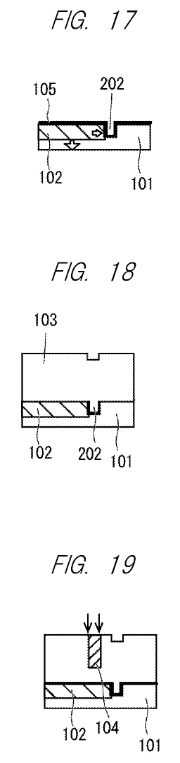

As illustrated in FIG. 17, the first impurity diffuses by the heat treatment, and the first impurity region 102 expands. At this point, the trench 202 suppresses diffusion of the first impurity in the lateral direction. However, while the diffusion of the first impurity in the lateral direction is suppressed by the trench 202, a part of the first impurity diffuses into a region under the trench 202. In the step of forming the first impurity region, the first impurity may be diffused so as to reach the trench 202. An oxide film 105 is formed on the upper surface of the first semiconductor layer 101. Before forming a second semiconductor layer 103, the oxide film 105 is removed. Thereafter, as illustrated in FIG. 18, the second semiconductor layer 103 is formed on the first semiconductor layer 101 by an epitaxial growth method. The thickness of the second semiconductor layer 103 is, for example, 4 μm or more and 6 μm or less. At this point, a recess is formed in an upper surface of the second semiconductor layer 103 in accordance with the trench 202. That is, the recess is formed so as to overlap the trench 202 in plan view.

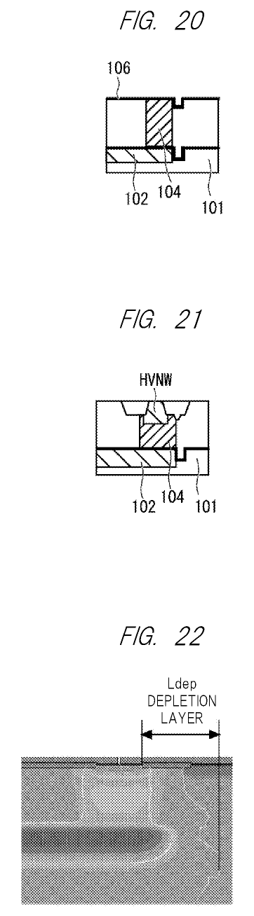

Next, as illustrated in FIG. 19, a second impurity of the first conductivity type is implanted into the second semiconductor layer 103. The second impurity is, for example, phosphorus. By introducing the second impurity into the second semiconductor layer 103, a second impurity region 104 is formed in the second semiconductor layer 103. Next, as illustrated in FIG. 20, the second impurity diffuses by the heat treatment, and the second impurity region 104 expands. The first impurity region 102 and the second impurity region 104 are connected to each other. In addition, an oxide film 106 is formed on the upper surface of the semiconductor substrate.

Subsequently, a semiconductor element 114 is formed in the element formation region. In addition, as illustrated in FIG. 21, an electrode HVNW is formed in the second impurity region 104. The first method of manufacturing the semiconductor device of the present disclosure includes the above steps. By forming the trench 202, diffusion of the first impurity region can be suppressed, and as a result, an increase in the size of the semiconductor device can be suppressed.

### SEMICONDUCTOR DEVICE OF PRESENT DISCLOSURE

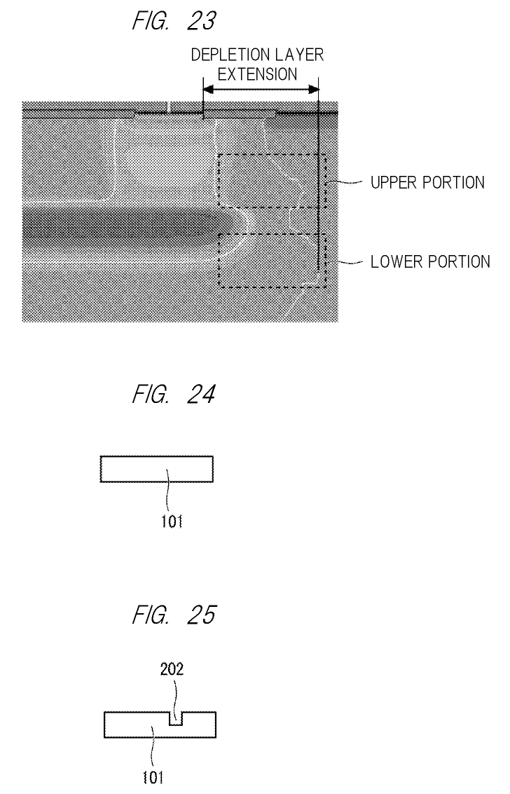

FIG. 22 is a diagram illustrating extension of a depletion layer in the semiconductor device of the present disclosure. FIG. 23 is a diagram illustrating extension of the depletion layer in the semiconductor device of the present disclosure. The semiconductor device of the present disclosure will be described with reference to FIGS. 22 and 23. As illustrated in FIG. 22, the first impurity has a concentration peak, and in the lateral direction, a concentration gradient between the concentration peak of the first impurity and an edge of the first impurity region is steep. A concentration gradient of the first impurity region 102, which has an impurity concentration lower than the concentration peak, in the lateral direction at an upper portion or a lower portion thereof is gentle. In addition, the concentration gradient of the impurity in the lateral direction is steeper than the concentration gradient of the impurity in the vertical direction.

As illustrated in FIG. 23, depletion layer extends from the lower portion and the upper portion of the sinker. As illustrated in FIG. 23, when the depth of the trench 202 is relatively small, the lower portion of the first impurity region 102 tends to diffuse into a region located under the trench 202. With the above configuration, diffusion of impurities toward a peripheral portion of the semiconductor element can be suppressed, and extension of the depletion layer can be suppressed.

Furthermore, as a feature of the semiconductor device of the present disclosure, as illustrated in FIG. 21, since a step is generated over the trench 202 after the second semiconductor layer 103 is formed by epitaxial growth, a step is also generated on an upper surface of a Shallow Trench Isolation (STI) formed on an upper surface of the second semiconductor layer 103. Therefore, parasitic capacitance can be reduced. That is, the semiconductor device of the present disclosure further includes an element isolation structure (STI) formed on an upper surface of the semiconductor substrate outside the element formation region, and a step is formed on an upper surface of the element isolation structure.

### SECOND METHOD OF MANUFACTURING SEMICONDUCTOR DEVICE OF PRESENT DISCLOSURE

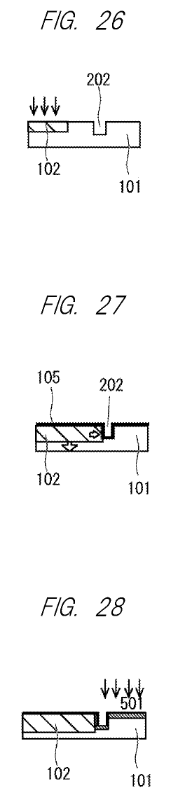

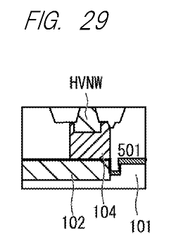

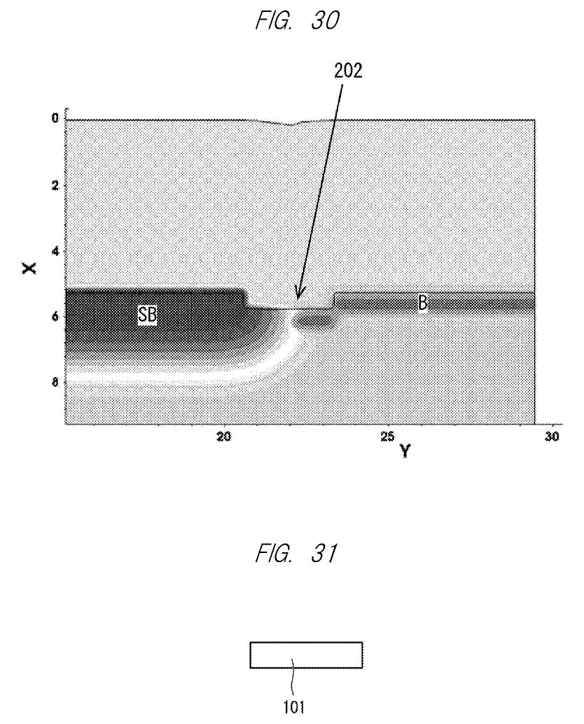

FIGS. 24 to 29 are flow diagrams illustrating a second method of manufacturing the semiconductor device of the present disclosure. FIG. 30 is a diagram illustrating an effect of the second method of manufacturing the semiconductor device of the present disclosure. The second method of manufacturing the semiconductor device of the present disclosure will be described with reference to FIGS. 24 to 30.

The second method of manufacturing the semiconductor device of the present disclosure differs from the first method of manufacturing the semiconductor device of the present disclosure in that a third impurity region 501 is formed.

Since the steps up to the heat treatment illustrated in FIGS. 24 to 27 are common to both the first method of manufacturing the semiconductor device and the second method of manufacturing the semiconductor device of the present disclosure, a detailed description thereof will be omitted. After performing the heat treatment illustrated in FIG. 27, as illustrated in FIG. 28, a third impurity region 501 of a second conductivity type opposite to the first conductivity type is formed in the first semiconductor layer 101 and on the upper surface of the first semiconductor layer 101 by implanting a third impurity into the first semiconductor layer 101. The third impurity is, for example, boron. That is, the third impurity region 501 is formed at the same level as the first impurity region.

In addition, the third impurity region 501 may be formed on a bottom surface of the trench 202. Therefore, the third impurity region 501 has a level difference between the bottom surface of the trench 202 and the upper surface of the first semiconductor layer 101.

As illustrated in FIG. 30, the third impurity region 501 (B) formed on the bottom surface of the trench 202 suppresses diffusion of the first impurity region (SB). In this manner, punch‑through in the semiconductor device can be suppressed, and a distance between adjacent semiconductor elements can be reduced.

### THIRD METHOD OF MANUFACTURING SEMICONDUCTOR DEVICE OF PRESENT DISCLOSURE

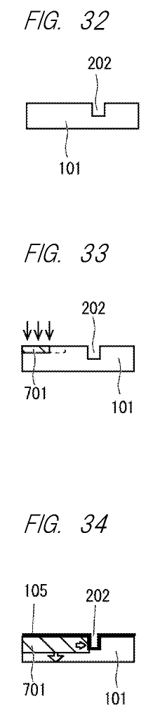

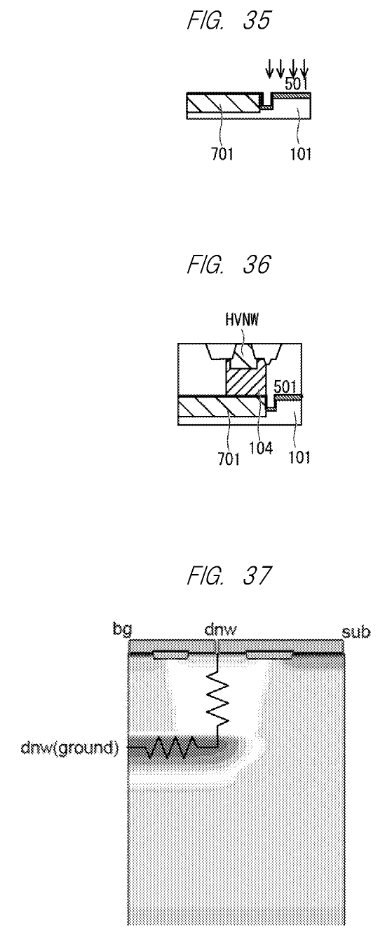

FIGS. 31 to 36 are flow diagrams illustrating a third method of manufacturing the semiconductor device of the present disclosure. FIG. 37 is a diagram illustrating a resistance between a sinker and a first impurity region formed by the third method of manufacturing the semiconductor device of the present disclosure. The third method of manufacturing the semiconductor device of the present disclosure will be described with reference to FIGS. 31 to 37.

The third method of manufacturing the semiconductor device of the present disclosure differs from the second method of manufacturing the semiconductor device of the present disclosure in that an area in which a first impurity is implanted is reduced. Since the other steps are the same as those in the second method of manufacturing the semiconductor device of the present disclosure, a detailed description thereof will be omitted.

As illustrated in FIG. 33, compared with the second method of manufacturing the semiconductor device of the present disclosure, an area in which a first impurity is implanted is reduced, and a first impurity region 701 is formed in the first semiconductor layer 101. The first impurity is, for example, antimony. As a result, diffusion of the first impurity can be more effectively suppressed by the trench 202, and expansion of the first impurity region 701 can be suppressed.

However, by suppressing diffusion of the first impurity region 102, a contact area between the first impurity region 102 and the second impurity region 104 may become smaller. For example, as illustrated in FIG. 40, resistance may occur between the first impurity region 102 and the second impurity region 104. Therefore, the reduction of the first impurity region 102 needs to be appropriately adjusted.

### FOURTH METHOD OF MANUFACTURING SEMICONDUCTOR DEVICE OF PRESENT DISCLOSURE

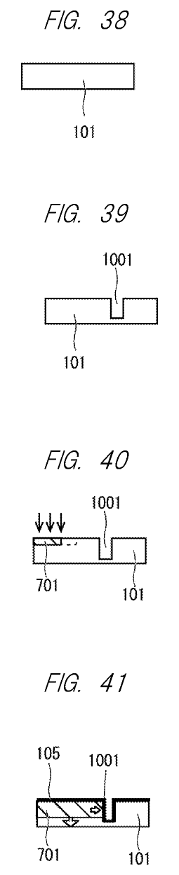

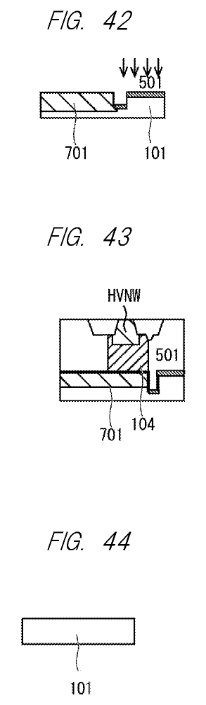

FIGS. 38 to 43 are flow diagrams illustrating a fourth method of manufacturing the semiconductor device of the present disclosure. The fourth method of manufacturing the semiconductor device of the present disclosure will be described with reference to FIGS. 38 to 43.

The fourth method of manufacturing the semiconductor device of the present disclosure differs from the third method of manufacturing the semiconductor device of the present disclosure in that a trench 1001 is formed deeper. Since the other methods of manufacturing are the same as those of the third method of manufacturing, a detailed description thereof will be omitted.

As illustrated in FIG. 39, the trench 1001 is formed deeper than the trench 202 formed in the third method of manufacturing. For example, the depth of the trench 1001 is made greater than the depth of the first impurity region 701 after diffusion of the first impurity. As illustrated in FIG. 41, the trench 1001 may be formed deeper than the depth of the first impurity region 701. As a result, a portion of the first impurity region 701 becomes less likely to diffuse into a region under the trench 1001.

### FIFTH METHOD OF MANUFACTURING SEMICONDUCTOR DEVICE OF PRESENT DISCLOSURE

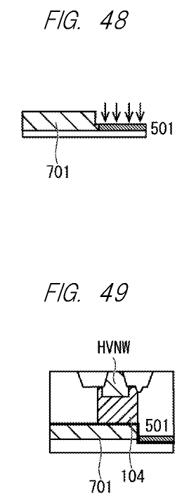

FIGS. 44 to 49 are flow diagrams illustrating a fifth method of manufacturing the semiconductor device of the present disclosure. The fifth method of manufacturing the semiconductor device of the present disclosure will be described with reference to FIGS. 44 to 49.

The fifth method of manufacturing the semiconductor device of the present disclosure differs from the third method of manufacturing the semiconductor device of the present disclosure in that a trench 1101 is formed by etching an entire outer peripheral surface. Since the other methods of manufacturing are the same as those of the third method of manufacturing, a detailed description thereof will be omitted.

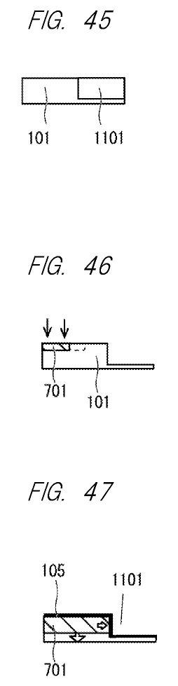

As illustrated in FIG. 45, a trench 1101 is formed at an upper surface of the first semiconductor layer 101 by etching an entire outer peripheral surface. The trench 1101 is formed outside the element formation region. In a subsequent heat treatment step, diffusion of the first impurity to the outside of the element formation region can be suppressed by the trench 1101, so that expansion of the first impurity region 701 can be suppressed.

For example, in the semiconductor device according to the above embodiments, the conductivity types (p‑type or n‑type) of the semiconductor substrate, the first semiconductor layer, the diffusion layer (diffusion region), and the second semiconductor layer may be reversed. Therefore, in a case where one of the n‑type and p‑type is defined as a first conductivity type and the other of the n‑type and p‑type is defined as a second conductivity type, the first conductivity type may be p‑type and the second conductivity type may be n‑type, or conversely, the first conductivity type may be n‑type and the second conductivity type may be p‑type.

In the foregoing, the invention made by the inventor of the present application has been concretely described on the basis of the embodiments. However, it is needless to say that the present invention is not limited to the foregoing embodiments, and various modifications and alterations can be made within the scope of the present invention.

What is claimed is:

1. A method of manufacturing a semiconductor device, the method comprising:
forming a first trench at an upper surface of a first semiconductor layer;
introducing a first impurity of a first conductivity type into the first semiconductor layer so as to be spaced apart from the first trench;
forming a first impurity region by diffusing the first impurity by heat treatment;
forming a second semiconductor layer on the first semiconductor layer by epitaxial growth;
introducing a second impurity of the first conductivity type into the second semiconductor layer;
forming a second impurity region so as to be connected to the first impurity region by diffusing the second impurity by heat treatment; and
forming a semiconductor element on the second semiconductor layer.

2. The method according to claim 1,
wherein, in forming the first impurity region, the first impurity is diffused so as to reach the first trench.

3. The method according to claim 1,
wherein the first trench is formed deeper than a depth of the first impurity region.

4. The method according to claim 1,
wherein the semiconductor device includes an element formation region,
wherein the first impurity region is formed in the element formation region, and
wherein the first trench and the second impurity region are formed so as to surround the element formation region in plan view.

5. The method according to claim 4, comprising:
after forming the first impurity region, introducing a third impurity of a second conductivity type, which is opposite to the first conductivity type, into the second semiconductor layer outside the element formation region.

6. The method according to claim 5,
wherein the first conductivity type is n‑type, and
wherein the second conductivity type is p‑type.

7. The method according to claim 5,
wherein the first impurity is antimony,
wherein the second impurity is phosphorus, and
wherein the third impurity is boron.

8. The method according to claim 1,
wherein, in forming the first trench, a second trench is formed at the upper surface of the first semiconductor layer, and
wherein the second trench is used as an alignment mark.

9. A semiconductor device comprising:
a semiconductor substrate;
a semiconductor element formed in an element formation region and on the semiconductor substrate; and
a first impurity region of a first conductivity type located under the semiconductor element and formed in the semiconductor substrate,
wherein a concentration gradient in a lateral direction from a concentration peak in the first impurity region is steeper than a concentration gradient in the lateral direction from a region located under the concentration peak.

10. The semiconductor device according to claim 9, further comprising:
a second impurity region of the first conductivity type formed in the semiconductor substrate,
wherein the second impurity region surrounds the element formation region, and
wherein the second impurity region is connected to the first impurity region.

11. The semiconductor device according to claim 9, further comprising:
a third impurity region of a second conductivity type opposite to the first conductivity type formed in the semiconductor substrate and outside the element formation region.

12. The semiconductor device according to claim 11,
wherein a step is formed at an upper surface of the third impurity region.

13. The semiconductor device according to claim 9, further comprising:
an element isolation structure formed at the upper surface of the semiconductor substrate and outside the element formation region,
wherein a step is formed at an upper surface of the element isolation structure.

14. The semiconductor device according to claim 11,
wherein the first impurity is antimony, and
wherein the third impurity is boron.

15. The semiconductor device according to claim 11,
wherein the first conductivity type is n‑type, and
the second conductivity type is p‑type.
